(19) United States
(12) Patent Application Publication
(10) Pub. No.: US 2021/0151511 A1
(43) Pub. Date: May 20, 2021

(54) DISPLAY DEVICE HAVING FINGERPRINT RECOGNITION SENSOR COUPLED THERETO

(71) Applicant: HiDeep Inc., Seongnam-si, Gyeonggi-do (KR)

(72) Inventors: Bon Kee KIM, Seongnam-si, Gyeonggi-do (KR); Young Ho CHO, Seongnam-si, Gyeonggi-do (KR)

(73) Assignee: HiDeep Inc., Seongnam-si, Gyeonggi-do (KR)

(21) Appl. No.: 16/623,031

(22) PCT Filed: Aug. 14, 2018
(86) PCT No.: PCT/KR2018/009316

§ 371 Date: Dec. 16, 2019

(30) Foreign Application Priority Data
Aug. 17, 2017 (KR) 10-2017-0104090

(51) Int. Cl. H01L 27/32; H01L 51/52; G06F 3/041; G06F 3/042; G06K 9/00; G02B 3/00

(52) U.S. Cl. CPC H01L 27/323; H01L 51/5275; H01L 27/3227; G02B 3/0056; G06F 3/042; G06K 9/0004; G06F 3/0412

(57) ABSTRACT

A display device having a sensor coupled thereto according to one embodiment of the present invention comprises: a cover layer; a display panel disposed below the cover layer; an optical layer disposed below the display panel; and an image sensor disposed below the optical layer. The optical layer includes: a microlens array layer including a plurality of microlenses; and an aperture layer which is disposed below the microlens array layer and includes holes each spaced apart from the microlenses by a focal length of the microlens. According to one embodiment of the present invention, a distance from a fingerprint to a fingerprint sensor can be greatly decreased in comparison with a conventional technology. In addition, deterioration of fingerprint image quality due to scattered light can be reduced.

### TECHNICAL FIELD

The present invention relates to a display device combined with a fingerprint recognition sensor, and more specifically, to a display device which improves fingerprint recognition performance of a fingerprint recognition sensor combined with the display device.

### BACKGROUND ART

Fingerprints are widely used for user authentication in a smart phone or a payment means. For this purpose, a fingerprint recognition device is installed in the smart phone or the payment means, such as a credit card or the like, in many cases. Although a separate fingerprint recognition device is used conventionally to recognize a fingerprint, attempts have been made recently to combine a fingerprint recognition with a display.

For example, in U.S. Pat. Nos. 8,994,690 and 9,336,428, it is configured to recognize a fingerprint by adding an image sensor or a capacitive sensor layer for fingerprint recognition to a liquid crystal display (LCD).

However, in the case of adding a fingerprint recognition sensor to a display, light reflected from a fingerprint should pass through a display layer and arrive at the fingerprint recognition sensor. However, since the distance between the fingerprint and the sensor is relatively long and the light is diffusely reflected by ridges and valleys of the fingerprint, it is difficult to acquire an accurate fingerprint image.

A hole (aperture) having a high aspect ratio is formed on each pixel of an image sensor as shown in US Laid-opened Patent No. 2016/0254312 to solve the problem of diffused reflection. However, since the depth of the hole should have a value close to 200 micrometers to get a high aspect ratio, it is difficult to form the hole in a semiconductor process. In addition, since the distance from the fingerprint to the fingerprint sensor is inevitably long as the hole is deep, brightness of an acquired fingerprint is low.

### DISCLOSURE OF INVENTION

### Technical Problem

Therefore, the present invention has been made in view of the above problems, and it is an object of the present invention to provide a display device combined with a fingerprint recognition sensor, which reduces the distance from a fingerprint to a fingerprint sensor.

Another object of the present invention is to provide a display device combined with a fingerprint recognition sensor, which allows only the light entering almost vertically, among the light reflected from a fingerprint, to enter a fingerprint sensor.

Still another object of the present invention is to provide a display device combined with a fingerprint recognition sensor, which can be formed merely through a semiconductor process.

### Technical Solution

To accomplish the above objects, according to one aspect of the present invention, there is provided a display device comprising: a cover layer; a display panel disposed under the cover layer; an optical layer disposed under the display panel; and an image sensor disposed under the optical layer. The optical layer includes: a microlens array layer including a plurality of microlenses; and an aperture layer disposed under the microlens array layer and provided with holes spaced apart from the microlenses as much as the focal length of the microlenses. The microlens array layer may be provided with a transparent or translucent substrate and a plurality of microlenses formed to protrude on the top surface of the substrate. The substrate may have a thickness making the distance from the microlens to the hole be equal to a focal length, and the aperture layer may be formed to be attached on the bottom surface of the substrate. According to embodiments, the microlens array layer may be formed to protrude on the bottom surface of the substrate. The substrate may further include a light blocking wall formed between the microlenses and may include a light blocking layer in the portions where the microlenses are not formed.

### Advantageous Effects

According to an embodiment of the present invention, since a microlens array layer can be formed to have a thickness of several micrometers to tens of micrometers approximately, the distance from a fingerprint to a fingerprint sensor can be reduced greatly in comparison with a conventional technique. In addition, since the microlens array layer can be created through a semiconductor process and mounted on an image sensor, a display device combined with a fingerprint recognition sensor can be formed merely through the semiconductor process. In addition, since only the light vertically reflected from a fingerprint may enter the image sensor, degradation of fingerprint image quality caused by scattered light can be reduced.

### DESCRIPTION OF DRAWINGS

FIG. 1 is a conceptual view schematically showing the cross-section of a display device combined with a fingerprint recognition sensor according to an embodiment of the present invention.

FIG. 2 is a conceptual view schematically showing the cross-section of a cover layer and a display panel when a rigid AMOLED is used as the display panel.

FIG. 3 is a conceptual view schematically showing the cross-section of a cover layer and a display panel when a flexible AMOLED is used as the display panel.

FIG. 4 is a conceptual view schematically showing the cross-section of a cover layer and a display panel when a flexible AMOLED of another form is used as the display panel.

FIG. 5 is a mimetic view showing the cell structure of an image sensor.

FIG. 6 is a cross-sectional mimetic view showing a view of disposing an optical layer on an image sensor in an embodiment of the present invention.

FIG. 7 is a conceptual view showing the disposition relation of the optical layer and the image sensor according to an embodiment of the present invention.

FIG. 8 is a conceptual view showing the disposition relation of the optical layer and the image sensor according to another embodiment of the present invention.

FIG. 9 is a conceptual view showing the disposition relation of the optical layer and the image sensor according to still another embodiment of the present invention.

FIG. 10 is a conceptual view showing the light reflected from a fingerprint and entering the photodiode region in the embodiment of FIG. 7.

FIG. 11 is a conceptual view showing the light reflected from a fingerprint and entering the photodiode region in the embodiment of FIG. 8.

FIG. 12 is a view illustrating the concept of forming a microlens array layer including a plurality of microlenses.

FIG. 13 is a view showing an embodiment of manufacturing a master mold in a thermal reflow method and manufacturing a microlens array layer using the master mold.

FIG. 14 is a view showing an embodiment of manufacturing a master mold in a 3D diffuser lithography method and manufacturing a microlens array layer using the master mold.

### MODE FOR INVENTION

The detailed description of the present invention will be described below with reference to the accompanying drawings which show a specific embodiment that the present invention can be embodied as an example. The embodiments are described in detail to be sufficiently so that those skilled in the art may understand to implement the present invention. It should be understood that although the diverse embodiments of the present invention are different from each other, they do not need to be mutual exclusive. For example, specific shapes, structures and features described herein may be implemented in another embodiment without departing from the spirit and scope of the present invention in relation to an embodiment. In addition, it should be understood that the locations or disposition of individual components in each disclosed embodiment may be changed without departing from the spirit and scope of the present invention. Therefore, the detailed description described below does not intend to be taken in a limited sense, and the scope of the present invention is limited by only the attached claims if properly explained, together with all the scopes equivalent to the claims. Like reference numerals in the drawings denote similar or like functions in several aspects.

Hereinafter, a display device combined with a fingerprint recognition sensor according to an exemplary embodiment of the present invention will be described with reference to the accompanying drawings.

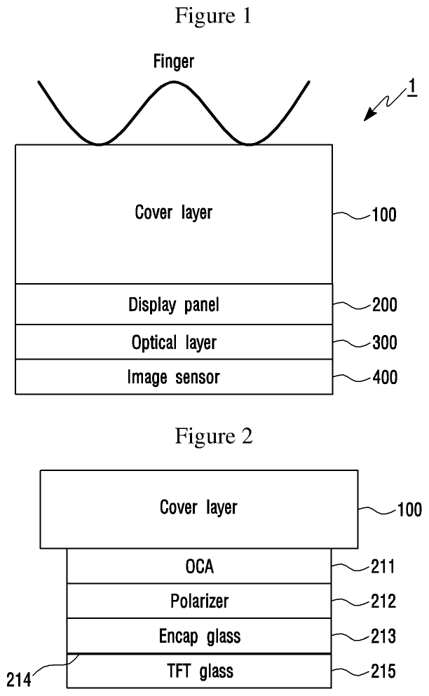

FIG. 1 is a cross-sectional view schematically showing the configuration of a display device combined with a fingerprint recognition sensor according to an embodiment of the present invention.

A display device 1 according to an embodiment of the present invention is provided with a cover layer 100, a display panel 200 disposed under the cover layer 100, an optical layer 300 disposed under the display panel 200, and an image sensor 400 disposed under the optical layer.

Cover glass generally used in a smart phone or the like may be used as the cover layer 100, and tempered glass, plastic or the like may be used. Although it varies depending on the material and design, generally, the cover layer 100 has a thickness of approximately 550 to 700 micrometers. Any display panel having a structure capable of transmitting light to the image sensor 400 like an AMOLED panel may be used as the display panel 200, and an AMOLED display panel generally has a thickness of 350 to 750 micrometers. The optical layer 300 is provided with a microlens array layer including a plurality of microlenses and an aperture layer so that only the light vertically reflected from a finger may be transferred to the image sensor 400. Although a CMOS image sensor may be preferably used as the image sensor 400, it is not limited thereto. In an embodiment, the image sensor 400 is disposed only under a certain region of the display panel 200, and the optical layer 300 is not disposed in the other regions.

FIG. 2 is a conceptual view schematically showing the cross-section of a cover layer and a display panel when a rigid AMOLED is used as the display panel. When a rigid AMOLED is used, the display panel 200 is provided with an OLED display layer 214 disposed between an encap glass 213 and a TFT glass 215, a polarizer layer 212 disposed on the encap glass 213, and an optical clear adhesive (OCA) 211 for adhering the polarizer layer 212 to the cover layer 100. The optical clear adhesive (OCA) 211 has a thickness of approximately 200 micrometers, the polarizer layer 212 has a thickness of 150 micrometers, the encap glass 213 has a thickness of 200 micrometers, the TFT glass 215 has a thickness of 200 micrometers, and the OLED display layer 214 has a thickness ignorable in comparison with the thickness of the other layers. Accordingly, when a rigid AMOLED is used as the display panel 200, thickness of the display panel 200 is approximately 750 micrometers.

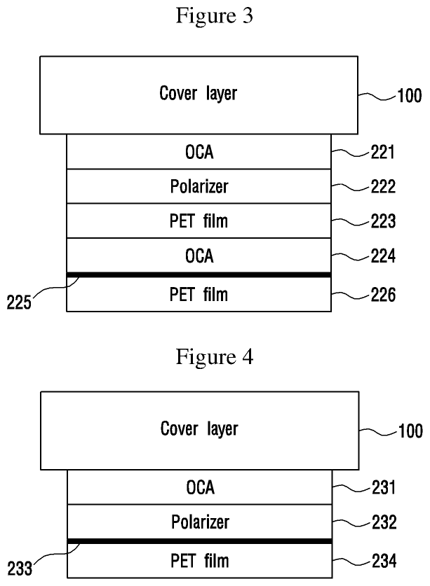

FIG. 3 is a conceptual view schematically showing the cross-section of a cover layer and a display panel when a flexible AMOLED is used as the display panel. When a flexible AMOLED as shown in FIG. 3 is used, the display panel 200 is provided with an OLED display layer 225 formed on a PET film 226, a PET film 223 adhered thereon through an optical clear adhesive (OCA) 224, a polarizer layer 222, and an optical clear adhesive (OCA) 221 for adhering these layers to a cover layer 100. In addition, a touch sensor may be formed on the PET film 223. Although not shown in the figure, the OLED display layer 225 may be provided with an encap film and a TFT film, each having a thickness of approximately 8 micrometers. In the configuration of FIG. 3, the optical clear adhesives (OCA) 221 and 224 respectively have a thickness of approximately 100 micrometers, the polarizer layer 222 has a thickness of approximately 150 micrometers, the upper PET film 223 has a thickness of approximately 40 micrometers, the lower PET film 223 has a thickness of approximately 100 micrometers, and the OLED display layer 225 has a thickness ignorable in comparison with the thickness of the other layers. Accordingly, when a flexible AMOLED of the configuration as shown in FIG. 3 is used as the display panel 200, thickness of the display panel 200 is approximately 500 micrometers.

FIG. 4 is a conceptual view schematically showing the cross-section of a cover layer and a display panel when a flexible AMOLED of another form is used as the display panel. When a flexible AMOLED as shown in FIG. 4 is used, the display panel 200 may be provided with an OLED display layer 233 formed on a PET film 234, a polarizer layer 232, and an optical clear adhesive (OCA) 231 for adhering these layers to a cover layer 100. In addition, a touch sensor may be formed on the OLED display layer 233. Although not shown in the figure, the OLED display layer 233 may be provided with an encap film and a TFT film, each having a thickness of approximately 8 micrometers. In the configuration of FIG. 3, the optical clear adhesive (OCA) 231 has a thickness of approximately 100 micrometers, the polarizer layer 232 has a thickness of approximately 150 micrometers, the PET film 234 has a thickness of approximately 100 micrometers, and the OLED display layer 233 has a thickness ignorable in comparison with the thickness of the other layers. Accordingly, when a flexible AMOLED of the configuration as shown in FIG. 4 is used as the display panel 200, thickness of the display panel 200 is approximately 350 micrometers.

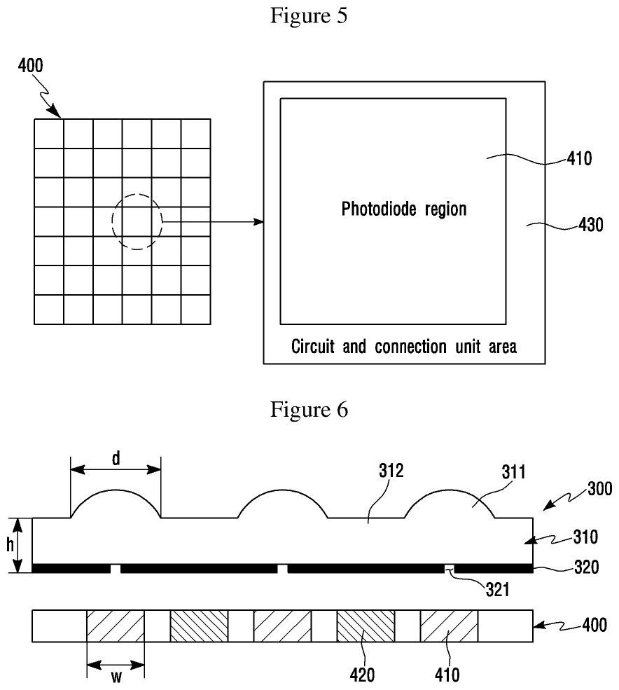

Next, the cell structure of a general image sensor will be described with reference to FIG. 5. FIG. 5 is a mimetic view showing the cell structure of an image sensor as an example. The image sensor 400 is provided with a plurality of cells or pixels disposed on a two-dimensional plane. As shown on the right side in FIG. 5, each cell has a photodiode region 410 for sensing light, and a circuit and connection unit region 430 disposed around the photodiode region 410. The area of each cell varies according to the resolution (number of pixels) and the size of the image sensor 400. For example, when the size of the image sensor 400 is 10 mm×10 mm and the number of pixels is 200×200, each cell has an area of 50 μm×50 μm. If the cell has an area like this, the photodiode region 410 occupies an area of, for example, 40 μm×40 μm.

FIG. 6 shows a view of disposing an optical layer 300 on an image sensor 400 formed like this. The optical layer 300 is provided with a microlens array layer 310 including a plurality of microlenses 311, and an aperture layer 320 disposed under the microlens array layer 310 and provided with a plurality of holes 321 spaced apart from the microlens array layer 310 as much as the focal length of the microlenses 311. The plurality of microlenses 311 is formed to protrude on the top surface of a transparent or translucent substrate 312. The aperture layer 320 performs a function of passing light only through the plurality of holes 321. The substrate 312 has a thickness making the distance from the microlens 311 to the hole 321 be equal to the focal length. The aperture layer 320 may be formed to be attached on the bottom surface of the substrate 312. According to embodiments, it may be configured to form a supporter layer (not shown) between the aperture layer 320 and the image sensor 400 to maintain the distance between the aperture layer 320 and the image sensor 400.

Although it is the better if the size of the hole 321 is the smaller, if the size is too small, a light dispersion phenomenon may occur by the diffraction phenomenon of light. Since the diffraction phenomenon generally occurs in a hole of a size equal to or smaller than about twice the wavelength of light, the diameter of the hole is preferably one micrometer or longer as the wavelength of visible light is approximately around 0.5 um (500 nm).

Although it is shown in FIG. 6 that the microlenses 311 protrude on the opposite side of the image sensor 400 (i.e., formed to protrude on the top surface of the substrate 312), according to embodiments, the plurality of microlenses 311 may be configured to protrude toward the image sensor 400 (i.e., formed to protrude on the bottom surface of the substrate 312). In this case, the aperture layer 320 is disposed at a distance spaced apart from the bottom surface of the substrate 321 as much as the focal length of the microlens 311.

In FIG. 6, it is shown that only some of the photodiode regions 410 and 420 of the image sensor 400 are used for fingerprint recognition. That is, when the resolution of the image sensor 400 is high, it may be configured such that only some 410 of the photodiode regions 410 and 420 are used for fingerprint recognition, and the others 420 are not used. In this case, it is configured to dispose the holes 321 and the microlenses 311 only on the photodiode regions 410 for fingerprint recognition.

The height h of the substrate 321 of the microlens array layer 310 is equal to the focal length of the microlens 311. The focal length is determined by the radius of curvature and the refractive index of the microlens 311. The focal length f of a microlens 311 having a structure flat at one side and protruding at the other side (plano-convex structure) may be obtained by the mathematical expression shown below.

f=r/(n−1)

The diameter d of the microlens 311 is determined by the focal length f, the width w of the photodiode region 410 of the image sensor 400, and the distance from the hole 321 to the photodiode region 410. Alternatively, if the diameter d of the microlens 311 is determined, the distance from the hole 321 to the photodiode region 410 may be determined considering the focal length f and the width w of the photodiode region 410. Although the focal length varies according to the material (i.e., the refractive index) of the microlens 311, the resolution of the image sensor 400, the pixel size and the like, the focal length may be set to be several micrometers to tens of micrometers approximately, and accordingly, the microlens array layer may be formed to have a thickness of approximately several micrometers to tens of micrometers. Accordingly, the distance from the fingerprint to the fingerprint sensor may be reduce greatly in comparison with conventional techniques, and a display device combined with a fingerprint recognition sensor including the microlens array layer can be formed merely through a semiconductor process.

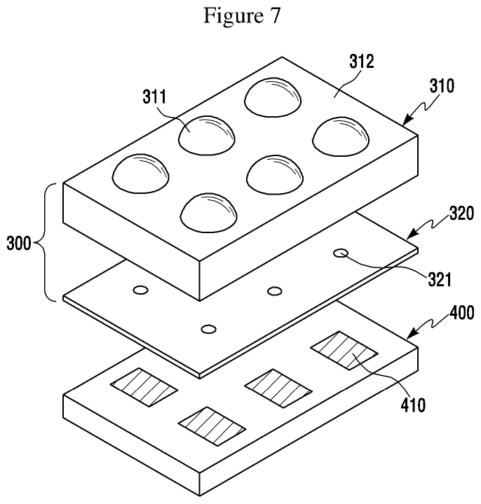

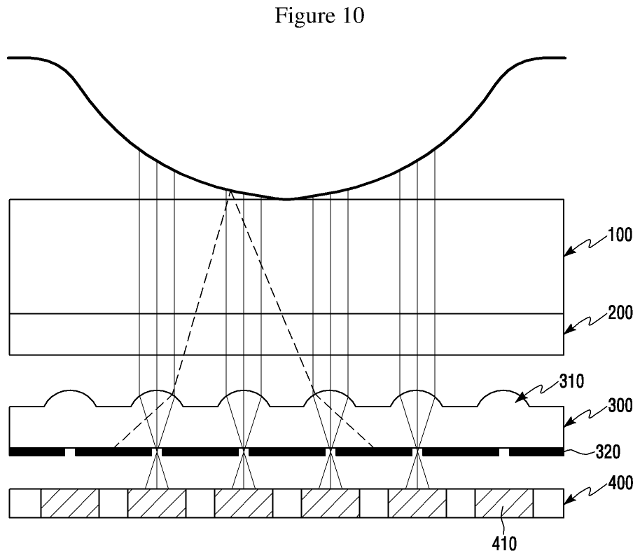

FIG. 7 is a conceptual view showing the disposition relation of the optical layer and the image sensor according to an embodiment of the present invention. The embodiment of FIG. 7 shows a case in which the microlenses 311 are one-to-one corresponding to the photodiode regions 410. FIG. 10 is a view showing the light reflected from a fingerprint and entering the photodiode region 410 in this case. As shown in FIG. 10, the light reflected from a fingerprint and entering the microlens in the perpendicular direction is collected at the focal point of the microlens 311 while passing through the microlens 311, passes through the hole 321 positioned at the focal length of the microlens 311, and arrives at the photodiode region 410 under the hole. Contrarily, the light reflected from the fingerprint and entering the microlens at an angle other than the perpendicular angle is blocked by the aperture layer 320 as is indicated by the dotted lines and may not arrive at the photodiode region 410. Accordingly, since only the light reflected from the fingerprint and entering the microlens in the perpendicular direction enters the photodiode region 410, the phenomenon of making the fingerprint image unclear by the scattered light can be prevented.

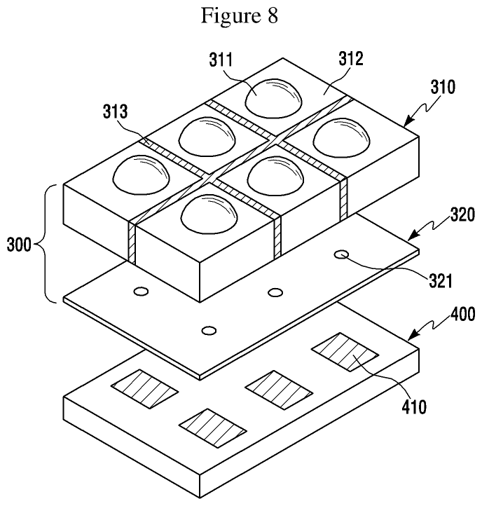

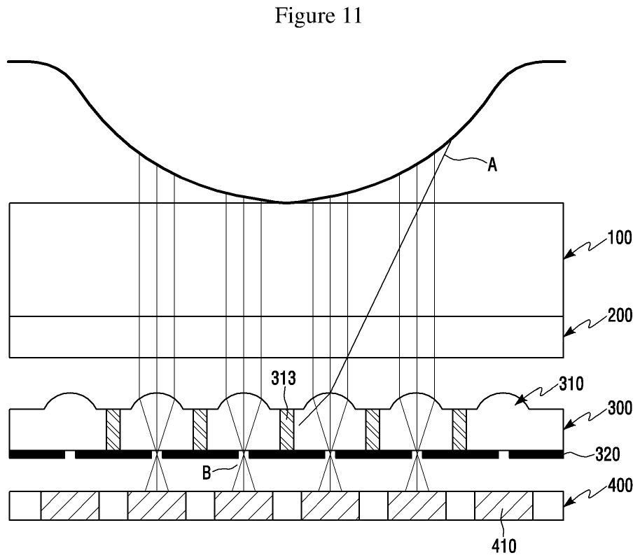

According to embodiments, a light blocking wall 313 for blocking the light passing through the microlens not to enter any other cells may be provided in the optical layer 300. FIG. 8 is a conceptual view showing the disposition relation of the optical layer and the image sensor of this case. FIG. 11 is a view showing the light reflected from a fingerprint and entering the photodiode region 410 in this case. As shown in FIG. 11, the light reflected from a fingerprint and entering the microlens in the perpendicular direction is collected at the focal point of the microlens 311 while passing through the microlens 311, passes through the hole 321 positioned at the focal length of the microlens 311, and arrives at the photodiode region 410 under the hole. Contrarily, the light reflected from the fingerprint and entering the microlens at an angle other than the perpendicular angle is blocked by the aperture layer 320 as is described in FIG. 10 and may not arrive at the photodiode region 410. In addition, light A directing toward a neighboring hole B, not the hole directly under the microlens through which the light has entered, among the light diffusely reflected from the fingerprint and entering the microlens at an angle other than the perpendicular angle, is blocked by the light blocking wall 313 and may not pass through the hole B as shown in FIG. 11. Accordingly, since only the light reflected from the fingerprint and entering the microlenses in the perpendicular direction enters the photodiode region 410, the phenomenon of making the fingerprint image unclear by the scattered light can be prevented. Meanwhile, although it is shown in FIGS. 8 and 11 that the light blocking wall 313 is formed to pass through from the top surface to the bottom surface of the substrate 312, the light blocking wall 313 may be formed not to be exposed to (i.e., not to pass through) the top surface and/or the bottom surface of the substrate 312.

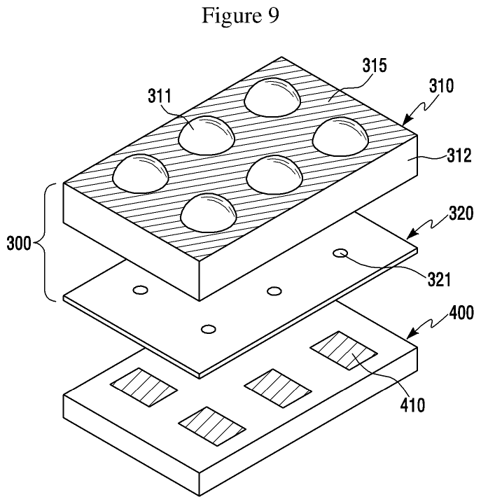

According to embodiments, a light blocking layer 315 for blocking the light passing through the microlens not to enter any other cells may be provided in the portions on the top surface of the substrate 312 of the optical layer 300, where the microlenses 311 are not formed. FIG. 9 is a conceptual view showing the disposition relation of the optical layer and the image sensor of this case. As shown in FIG. 9, since the light blocking layer 315 is provided in the portions on the top surface of the substrate 312, where the microlenses 311 are not formed, the light arriving at the portions on the top surface of the substrate 312, where the microlenses 311 are not formed, among the light diffusely reflected from the fingerprint and entering the microlenses at an angle other than the perpendicular angle, is blocked by the light blocking layer 315 and may not pass through the optical layer 300. Accordingly, the phenomenon of making the fingerprint image unclear by the scattered light can be prevented.

Meanwhile, according to embodiments, it may be configured, in the embodiment of FIG. 8, to provide the light blocking layer 315 in the portions on the top surface of the substrate 312, where the microlenses 311 are not formed, as shown in FIG. 9. In this case, the light blocking wall 313 and the light blocking layer 315 may be formed in one piece.

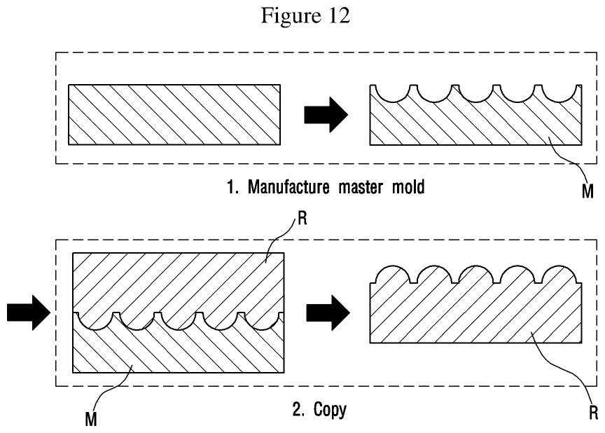

Next, some embodiments of forming a microlens array layer including a plurality of microlenses will be described with reference to FIGS. 12 to 14.

As shown in FIG. 12, generally, a microlens array layer is formed through a process of forming a master mold M, pouring a microlens material of liquid phase into the master mold M, forming a microlens array layer R by curing the liquid microlens material, and tearing off the microlens array layer R from the master mold M. Polycarbonate (PC), polymethyl methacrylate (PMMA), polydimethylsiloxane (PDMS), UV curable resin or the like may be used as the microlens material. Various methods such as heating, applying ultraviolet ray, drying and the like may be used as the curing method.

For example, a thermal reflow method or a 3D diffuser lithography method may be used as a method of forming the master mold.

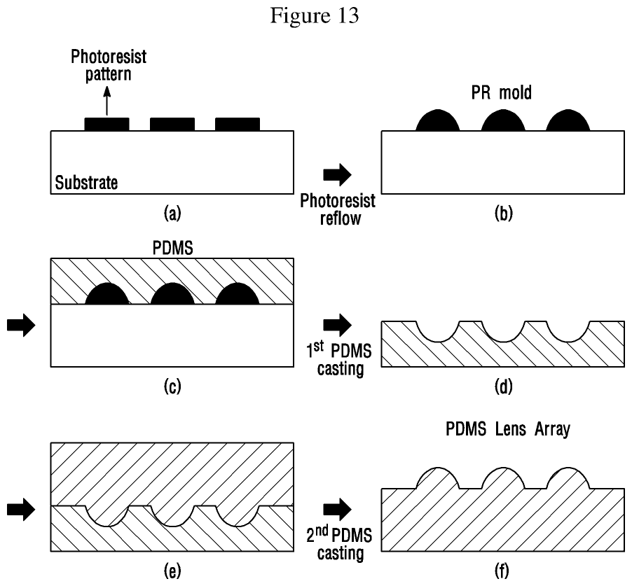

FIG. 13 is a view illustrating a thermal reflow method. (a) A photoresist pattern is formed in a plurality of portions on a substrate, in which microlenses will be formed, and (b) a plurality of photoresist (PR) molds shaped in the form of a convex lens is formed on the substrate by performing photoresist reflow. (c) Polydimethylsiloxane (PDMS) is poured into the mold, and (d) a master mold is obtained by performing primary PDMS casting. (e) A microlens material is poured into the master mold after manufacturing the master mold, and (f) a microlens array layer is created by performing secondary PDMS casting. A plurality of microlens array layers is created by performing the steps (e) and (f) several times for one master mold.

According to embodiments, a microlens array may be formed by performing only the steps (a) and (b) of FIG. 13 by using a photoresist of a transparent or translucent material on a substrate of a transparent or translucent material. If a method of forming a microlens array by forming a transparent or translucent photoresist pattern on a transparent or translucent substrate and performing photoresist reflow, a microlens array may be formed directly on a manufactured semiconductor wafer. For example, a microlens array may be directly formed on a semiconductor wafer by putting a substrate having an aperture layer formed on the bottom on an image sensor semiconductor wafer, forming a photoresist pattern on the substrate, and reflowing the photoresist.

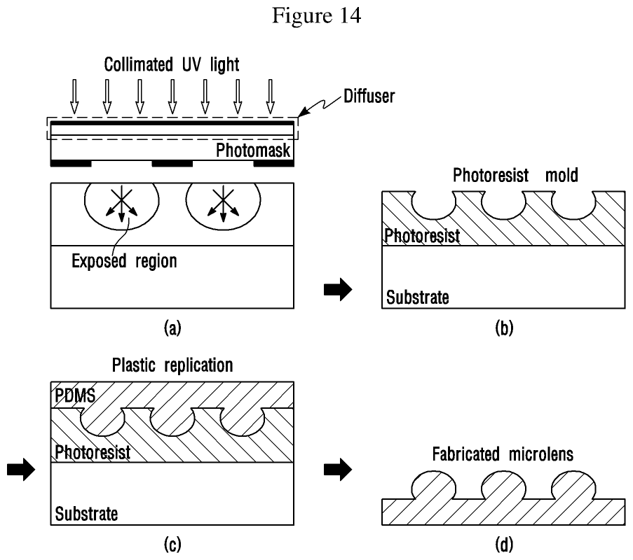

FIG. 14 is a view illustrating a 3D diffuser lithography method. (a) A photoresist layer is formed on a substrate, and a photomask having openings formed in a plurality of portions where microlenses will be formed is put the photoresist layer, and then collimated UV light is radiated toward the photomask through a diffuser. Then, the UV light scattered by the diffuser enters the exposed regions of the photoresist as is indicated by the arrows, and a master mold having a photoresist mold formed on the substrate is manufactured as shown in (b). (c) A microlens material is poured into the master mold after the master mold is manufactured, and (d) a microlens array is created by performing PDMS casting. A plurality of microlens arrays is created by performing the steps (c) and (d) several times for one master mold.

Meanwhile, as a method of forming the light blocking wall in the microlens array layer 310 in the embodiments of FIGS. 13 and 14, a method of forming a light blocking wall 313 by forming a mesh structure corresponding to the light blocking wall on the master mold, forming a microlens array having empty portions corresponding to the light blocking wall by pouring a microlens material therein, and pouring a light blocking material in the empty portions can be used.

In addition, as a method of forming the light blocking layer 315 on the microlens array layer 310 in the embodiments of FIGS. 13 and 14, a method of attaching a light blocking film having holes at the locations of microlenses on the top surface of the microlens array created through the processes of FIGS. 13 and 14 in a method of adhering, curing or the like can be used.

The features, structures, effects and the like described in the above embodiments are included in an embodiment of the present invention and not necessarily limited to only one embodiment. Furthermore, the features, structures, effects and the like illustrated in each embodiment may be combined or modified for other embodiments by those skilled in the art. Accordingly, contents related to the combination and modification should be interpreted as being included in the scope of the present invention.

Although the present invention has been described above focusing on the embodiments, this is only an example and does not limit the present invention, and it is to be appreciated that those skilled in the art may make various modifications and applications not mentioned above without departing from the essential characteristics of the embodiments. For example, each constitutional component specifically shown in the embodiments can be modified. In addition, the differences related to the modifications and applications should be interpreted as being included in the scope of the present invention defined by the appended claims.

### DESCRIPTION OF SYMBOLS

100: Cover layer
200: Display panel
300: Optical layer
310: Microlens array layer
311: Microlens
312: Substrate
320: Aperture layer
400: Image sensor
410: Photodiode region
420: Dummy photodiode region
430: Circuit and connection unit region

1. A display device comprising:
a cover layer,
a display panel disposed under the cover layer;
an optical layer disposed under the display panel; and
an image sensor disposed under the optical layer.

2. The device according to claim 1, wherein the optical layer includes:
a microlens array layer including a plurality of microlenses; and
an aperture layer disposed under the microlens array layer and provided with a plurality of holes spaced apart from the microlenses as much as a focal length of the microlenses.

3. The device according to claim 2, wherein the microlens array layer is provided with a transparent or translucent substrate and a plurality of microlenses formed to protrude on a top surface of the substrate.

4. The device according to claim 3, wherein the substrate has a thickness making a distance from the microlens to the hole be equal to the focal length, and the aperture layer is formed to be attached on a bottom surface of the substrate.

5. The device according to claim 2, wherein the microlens array layer is provided with a transparent or translucent substrate and a plurality of microlenses formed to protrude on a bottom surface of the substrate.

6. The device according to claim 2, wherein the substrate further includes a light blocking wall formed between the microlenses.

7. The device according to claim 2, wherein a light blocking layer is formed in portions of the top surface of the substrate, where the microlenses are not formed.

8. The device according to claim 2, wherein a diameter of the hole is one micrometer or larger.

9. The device according to claim 2, wherein the display panel is an organic light emitting diode (OLED) panel.
